(19) United States
(12) Patent Application Publication
(10) Pub. No.: US 2025/0006848 A1
(43) Pub. Date: Jan. 2, 2025

(54) ARRAY SUBSTRATE, METHOD FOR MANUFACTURING THE SAME, AND DISPLAY PANEL

(71) Applicants: MIANYANG HKC OPTOELECTRONICS TECHNOLOGY CO., LTD., Mianyang (CN); HKC CORPORATION LIMITED, Shenzhen (CN)

(72) Inventors: Xiufeng ZHOU, Mianyang (CN); Xin YUAN, Mianyang (CN); Chen CHEN, Mianyang (CN); Hailiang WANG, Mianyang (CN); Lidan YE, Mianyang (CN)

(73) Assignees: MIANYANG HKC OPTOELECTRONICS TECHNOLOGY CO., LTD., Mianyang (CN); HKC CORPORATION LIMITED, Shenzhen (CN)

(21) Appl. No.: 18/517,063

(22) Filed: Nov. 22, 2023

(30) Foreign Application Priority Data
Jun. 29, 2023 (CN) 202310777179.0

(51) Int. Cl. H01L 29/786; H01L 27/12; H01L 29/40; H01L 29/66; H10K 59/131

(52) U.S. Cl. CPC H01L 29/78696; H01L 27/1225; H01L 27/124; H01L 29/401; H01L 29/66969; H01L 29/78633; H10K 59/131; H01L 29/7869

(57) ABSTRACT

Related to the field of display panels, an array substrate, a manufacturing method thereof, and a display panel. The array substrate includes: the base substrate, the buffer layer, the active layer, the gate insulation layer, the gate, the interlayer insulation layer, the source, and the drain, which are stacked together. By using the gate insulation layer as a conductive mask of the active layer, and by adjusting the width of the gate and the width of the gate insulation layer, a width difference between the channel region and the gate is within the preset range, which reduces the problem of excessive width difference caused by the diffusion phenomenon of the channel region, and can at the same time meet the switching characteristics requirements of the thin film transistor and the definition requirements of the display panel.

### CROSS-REFERENCE TO RELATED APPLICATIONS

Pursuant to 35 U.S.C. §119 and the Paris Convention, this application claims the benefit of Chinese Patent Application No. 202310777179.0 filed Jun. 29, 2023, the contents of which are incorporated herein by reference.

### TECHNICAL FIELD

The present application relates to the technical field of display panels, and more particularly to an array substrate, a method for manufacturing the same, and a display panel.

### BACKGROUND

The statements here only provide background information related to this application, and do not necessarily constitute prior art. As an important component of a flat panel display device, a thin film transistor (TFT) can be formed on a glass substrate or a plastic substrate. TFT is usually used as a switching device and a driving device in a display apparatus, such as a liquid crystal display device (LCD) and an organic light emitting display (OLED).

When fabricating thin film transistors on a glass substrate or a plastic substrate, a gate is usually used as a conductive mask of the active layer to form a corresponding channel region. However, due to the diffusion phenomenon in different conductive processes, an actual width of the channel region is smaller than a width of the gate. Due to the definition requirements of the display panel, the size of the thin film transistor needs to be reduced as much as possible. If a difference between the width of the channel region and the width of the gate is too large, short-channel thin film transistors may lose their switching characteristics, therefore, the difference needs to be as small as possible. However, due to the diffusion effect, the difference cannot be ensured, and ultimately the switching characteristics requirements cannot be taken into account.

### SUMMARY

It is an object of embodiments of the present application to provide an array substrate, a fabrication method thereof, and a display panel, which aims at solving the technical problem that the traditional array substrate cannot take into account the switching characteristic requirements when meeting the definition requirements.

A first aspect of embodiments of the present application provides an array substrate. The array substrate comprises:

a base substrate; and

a buffer layer, an active layer, a gate insulation layer, and a gate, which are sequentially stacked on the base substrate.

The active layer is an oxide semiconductor layer, the gate is arranged within an orthographic projection of the gate insulation layer. The gate insulation layer is a conductive mask of the active layer. The active layer comprises: a channel region, which is arranged within the orthographic projection of the gate insulation layer, and source and drain contact regions, which are arranged at two sides of the channel region. The channel region is also arranged within an orthographic projection of the gate. The source and drain contact regions are conductors.

An interlayer insulation layer is formed on the buffer layer. The interlayer insulation layer covers the gate, the active layer, and the gate insulation layer. The interlayer insulation layer defines therein two first through holes, which are correspondingly arranged above the source and drain contact regions, respectively.

A source and a drain are arranged on the interlayer insulation layer, and the source and the drain are in connection with the two source and drain contact regions through the two first through holes, respectively.

Along a first direction, a relationship of a distance between an edge of the gate and an edge of the channel region is as follows:

ΔL<(1/5)*Lgate,

in which, ΔL represents the distance between the edge of the gate and the edge of the channel region, Lgate represents a width of the gate extending along the first direction, and the first direction is a direction in which a width of the channel region is extended.

Optionally, the gate insulation layer and the gate are sequentially deposited, exposed and developed, and etched on the active layer, such that the gate insulation layer having a preset extension width and the gate having a preset extension width along the first direction are formed.

Along the first direction, the distance between the edge of the gate insulation layer and the edge of the gate is Lbf, and Lbf ranges between (1/20)*Lgate and (1/2)Lgate.

Optionally, the interlayer insulation layer further defines therein a second through hole corresponding to the gate.

The array substrate further comprises a photoresist layer arranged on the interlayer insulation layer. The photoresist layer is in connection with the gate through the second through hole, and the photoresist layer is a conductor. The source, the photoresist layer, and the drain are sequentially arranged on a surface of the interlayer insulation layer along the first direction.

The gate insulation layer is arranged within an orthographic projection of the photoresist layer.

Optionally, the array substrate further comprises: a metal layer, a plurality of first wiring structures, and a plurality of second wiring structures.

The metal layer is arranged between the base substrate and the buffer layer. The buffer layer covers the metal layer. An extension direction of the metal layer intersects with an extension direction of the photoresist layer. In the first direction, the metal layer does not overlap with the gate.

The plurality of first wiring structures are arranged on the array substrate along a second direction. The plurality of second wiring structures are arranged on the array substrate along a third direction. The second direction intersects with the third direction.

The plurality of first wiring structures are wired through the photoresist layer.

The plurality of second wiring structures are wired through the metal layer.

A second aspect of embodiments of the present application provides a method for manufacturing a base substrate. The method comprises the following steps:

sequentially depositing a buffer layer, an active layer, a gate insulation layer, and a gate on a base substrate, in which, the active layer is an oxide semiconductor layer, and the gate is arranged within an orthographic projection of the gate insulation layer;

using the gate insulation layer as a mask to make the active layer conductive, to form a channel region arranged within the orthographic projection of the gate insulation layer and source and drain contact regions arranged at two sides of the channel region, in which, the channel region is arranged with an orthographic projection of the gate, and the source and drain contact regions are conductors;

depositing an interlayer insulation layer, to enable the interlayer insulation layer to cover the buffer layer, the gate, the active layer, and the gate insulation layer; and exposing and developing the interlayer insulation layer to define therein two first through holes which directly reach surfaces of the source and drain contact regions; and

depositing a source and a drain on the interlayer insulation layer and in the two first through holes.

Along a first direction, a relationship of a distance between an edge of the gate and an edge of the channel region is as follows:

ΔL<(1/5)*Lgate,

in which, ΔL represents the distance between the edge of the gate and the edge of the channel region, Lgate represents a width of the gate extending along the first direction, and the first direction is a direction in which a width of the channel region is extended.

Optionally, along the first direction, the distance between the edge of the gate insulation layer and the edge of the gate is Lbf, and Lbf ranges between (1/20)*Lgate and (1/2)Lgate.

Optionally, the method for manufacturing the base substrate further comprises:

exposing and developing the interlayer insulation layer to define therein a second through hole directly reaching a surface of the gate; and

depositing a photoresist layer on the interlayer insulation layer and in the second through hole.

The photoresist layer is a conductor. The source, the photoresist layer, and the drain are sequentially arranged on a surface of the interlayer insulation layer along the first direction.

The gate insulation layer is arranged within an orthographic projection of the photoresist layer.

Optionally, the method for manufacturing the base substrate further comprises:

depositing a metal layer on the base substrate, in which, the metal layer is arranged between the base substrate and the buffer layer, the buffer layer covers the metal layer, and an extension direction of the metal layer intersects with an extension direction of the photoresist layer; and in the first direction, the metal layer does not overlap with the gate; and

providing a plurality of first wiring structures and a plurality of second wiring structures, in which, the plurality of first wiring structures are arranged on the array substrate along a second direction, the plurality of second wiring structures are arranged on the array substrate along a third direction, the plurality of first wiring structures are wired through the photoresist layer, the plurality of second wiring structures are wired through the metal layer, and the second direction intersects with the third direction.

Optionally, the step of sequentially depositing the buffer layer, the active layer, the gate insulation layer, and the gate on the base substrate specifically comprises:

sequentially depositing the buffer layer and the active layer on the base substrate; and

sequentially depositing, exposing and developing, and etching the gate insulation layer and the gate on the active layer, so as to form the gate insulation layer having a preset extension width and the gate having a preset extension width along the first direction.

A third aspect of embodiments of the present application further provides a display panel, comprising an OLED device and an array substrate. The OLED device is stacked above the array substrate. The array substrate is the array substrate provided by the first aspect of embodiments of the present application or the array substrate manufactured by the method provided by the second aspect of embodiments of the present application.

The array substrate provided by embodiments of the first aspect of the present application comprises: the base substrate, the buffer layer, the active layer, the gate insulation layer, the gate, the interlayer insulation layer, the source, and the drain, which are stacked together. By using the gate insulation layer as a conductive mask of the active layer, and by adjusting the width of the gate and the width of the gate insulation layer, a width difference between the channel region and the gate is within the preset range, which reduces the problem of excessive width difference caused by the diffusion phenomenon of the channel region, and can at the same time meet the switching characteristics requirements of the thin film transistor and the definition requirements of the display panel.

It can be understood that the beneficial effects of the above-mentioned second aspect and the third aspect can be referred to the relevant description in the above-mentioned first aspect, and will not be repeated herein.

### BRIEF DESCRIPTION OF THE DRAWINGS

FIG. 1 is a first structural schematic diagram of an array substrate provided in Example 1 of the present application;

FIG. 2 is a second structural schematic diagram of the array substrate provided in Example 1 of the present application;

FIG. 3 is a structural schematic diagram of a display panel provided in Example 2 and Example 7 of the present application;

FIG. 4 is a structural schematic diagram of an array substrate provided in Example 2 of the present application;

FIG. 5 is a structural schematic diagram of sub-pixels provided in Example 3 of the present application;

FIG. 6 is a timing diagram of sub-pixels provided in Example 3 of the present application;

FIG. 7 is a first structural schematic diagram of an array substrate provided in Example 3 of the present application;

FIG. 8 is a second structural schematic diagram of the array substrate provided in Example 3 of the present application;

FIG. 9 is a third structural schematic diagram of the array substrate provided in Example 3 of the present application;

FIG. 10 is a schematic flow chart of a method for manufacturing an array substrate provided in Example 4 of the present application;

FIG. 11 is a schematic flow chart of step S10 provided in Example 4 of the present application;

FIG. 12 is a structural schematic diagram corresponding to step S10 provided in Example 4 of the present application;

FIG. 13 is a structural schematic diagram corresponding to step S20 provided in Example 4 of the present application;

FIG. 14 is a schematic flow chart of a method for manufacturing an array substrate provided in Example 5 of the present application;

FIG. 15 is a structural schematic diagram corresponding to step S50 provided in Example 5 of the present application;

FIG. 16 is a schematic flowchart of a method for manufacturing an array substrate provided in Example 6 of the present application.

### DETAILED DESCRIPTION OF THE EMBODIMENTS

In order to make the technical problems to be solved, the technical solutions, and advantages of the present application clearer, the present application will be further described in details in combination with the accompanying drawings and embodiments. It should be understood that the specific embodiments described here are only used to explain the present application, and are not used to limit the present application.

It should be noted that when a component is said to be “fixed on” or “installed on” another component, it can be directly or indirectly on the other component. When a component is said to be “connected” to another component, it can be directly or indirectly connected to the other component.

It should be understood that the terms “length”, “width”, “top”, “bottom”, “front”, “rear”, “left”, “right”, “vertical”, “horizontal”, “top” “bottom”, “inside”, “outside”, and the like indicate the orientation or positional relationship based on the orientation or positional relationship shown in the drawings, and are only for ease of description, and do not indicate or imply the device referred to or the element must have a specific orientation, and be constructed and operated in a specific orientation, and therefore cannot be construed as a limitation of the present application. For those skilled in the art, the specific meaning of the above terms can be understood according to specific conditions.

Moreover, the terms “first” and “second” are only used for ease of description, and cannot be understood as indicating or implying relative importance or implicitly indicating the number of technical features. The meaning of “plurality” means two or more than two, unless otherwise specifically defined.

### EXAMPLE 1

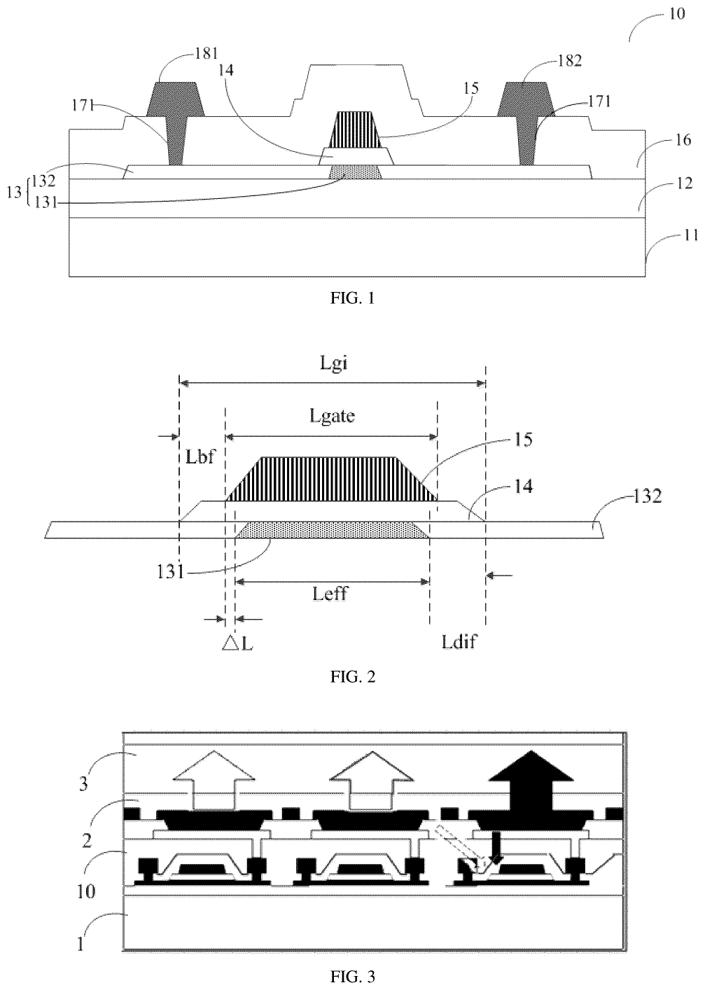

As shown in FIGS. 1-2, an array substrate 10 is provided by embodiments of the present application. The array substrate 10 comprises:

a base substrate 11; and

a buffer layer 12, an active layer 13, a gate insulation layer 14, and a gate 15 which are sequentially stacked on the base substrate 11.

The active layer 13 is an oxide semiconductor layer, the gate 15 is arranged within an orthographic projection of the gate insulation layer 14. The gate insulation layer 14 is a conductive mask of the active layer 13. The active layer 13 comprises: a channel region 131, which is arranged within the orthographic projection of the gate insulation layer 14, and source and drain contact regions 132, which are arranged at two sides of the channel region 131. The channel region 131 is also arranged within an orthographic projection of the gate 15. The source and drain contact regions 132 are conductors.

An interlayer insulation layer 16 is formed on the buffer layer 12. The interlayer insulation layer 16 covers the gate 15, the active layer 13, and the gate insulation layer 14. The interlayer insulation layer 16 defines therein two first through holes 171, which are correspondingly arranged above the source and drain contact regions 132, respectively.

A source 181 and a drain 182 are arranged on the interlayer insulation layer 16, and the source 181 and the drain 182 are in connection with the two source and drain contact regions 132 through the two first through holes 171, respectively.

Along a first direction, a relationship of a distance between an edge of the gate 15 and an edge of the channel region 131 is as follows:

ΔL<(1/5)*Lgate,

in which, ΔL represents the distance between the edge of the gate 15 and the edge of the channel region 131, Lgate represents a width of the gate 15 extending along the first direction, and the first direction is a direction in which a width of the channel region 131 is extended.

In embodiments of the present application, during the fabrication of the thin film transistor, the buffer layer 12, the active layer 13, the gate insulation layer 14, and the gate 15 are first stacked, a mask having a preset size is placed right above the gate 15, and then exposure and development are performed, so as to form the gate insulation layer 14 and the gate 15 having the same size, after that, the gate insulation layer 14 and the gate 15 are etched. By adjusting the etching process, a width difference between the gate insulation layer 14 and the gate 15 is ensured to be within the preset range and then the gate insulation layer 14 is used as a conductive mask to make the active layer 13 conductive so that the source and drain contact regions 132 form a conductor. Thereafter, the interlayer insulation layer 16 is stacked above the gate 15 and the active layer 13, and the first through holes 171, the source 181, and the drain 182 are formed correspondingly.

In case that the conductive process remains unchanged, due to the diffusion phenomenon, the difference between the width of the gate insulation layer 14 and the width of the channel region 131 remains unchanged. By adjusting the etching process, along the first direction, the width of the gate insulation layer 14 is greater than the width of the gate 15, and the width of the gate 15 is greater than the width of the channel region 131, so that the difference between the width of the gate 15 and the width of the channel region 131 is smaller than a preset value, that is, the distance between the edge of the gate 15 and the edge of the channel region 131 satisfies ΔL<(1/5)*Lgate. On the premise that the size of the thin film transistor is small enough to meet the definition of the display panel, the width of the channel region 131 is close to the width of the gate 15, so as to avoid the loss of switching characteristics of thin film transistors due to short channels.

Among them, the width of the gate insulation layer 14 is defined as Lgi, the width of the gate 15 is defined as Lgate, the width of the channel region 131 is defined as Leff, the difference between the width of the gate insulation layer 14 and the width of the channel region 131 is defined as Ldif, the difference between the width of the gate 15 and the width of the channel region 131 is defined as ΔL, and the difference between the width of the gate insulation layer 14 and the width of the gate 15 is defined as Lbf.

By sequentially depositing, exposing, developing, and etching the gate insulation layer 14 and the gate 15 on the active layer 13, the gate insulation layer 14 having a preset extension width and the gate 15 having a preset extension width along the first direction are formed. By improving the etching process and adjusting the appropriate Lbf value, when Ldif remains unchanged, it can be ensured that ΔL is smaller than a preset value, and Lbf satisfies Ldif−Lbf≤(1/5)*Lgate. In addition, due to the different sizes of Ldif under different conductive processes, in order to ensure that ΔL is smaller than the preset value, optionally, along the first direction, the distance between the edge of the gate insulation layer 14 and the edge of the gate 15 is Lbf, and Lbf ranges between (1/20)*Lgate and (1/2)Lgate. By appropriately adjusting the Lbf, the display panel can have high definition, and at the same time the switching characteristics of the thin film transistor can be ensured.

The array substrate 10 provided by embodiments of the present application comprises: the base substrate 11, the buffer layer 12, the active layer 13, the gate insulation layer 14, the gate 15, the interlayer insulation layer 16, the source 181, and the drain 182, which are stacked together. By using the gate insulation layer 14 as a conductive mask of the active layer 13, and by adjusting the width of the gate 15 and the width of the gate insulation layer 14, a width difference between the channel region 131 and the gate 15 is within the preset range, which reduces the problem of excessive width difference caused by the diffusion phenomenon of the channel region 131, and can at the same time meet the switching characteristics requirements of the thin film transistor and the definition requirements of the display panel.

### EXAMPLE 2

Based on Example 1, as shown in FIG. 3, an simplified schematic diagram of an OLED display panel is exemplarily illustrated. The OLED display panel comprises: a first substrate 3, OLED devices 2, an array substrate 10, and a second substrate 1, which are stacked together. The array substrate 10 comprises a plurality of thin film transistors. Each thin film transistor serves as a unit driving circuit and is in connection with a corresponding OLED device 2 to form a single sub-pixel. The OLED device 2 lights up according to a driving signal output by the corresponding unit driving circuit connected thereto, so that a corresponding image information can be displayed by all sub-pixels of the OLED display panel in combination.

In applications, the light emitted by the OLED devices 2 may be reflected or refracted through gaps to the thin film transistors below, affecting the TFT characteristics of the channel region 131, causing a shift in TFT characteristics, and ultimately reducing the display effect of the OLED display panel.

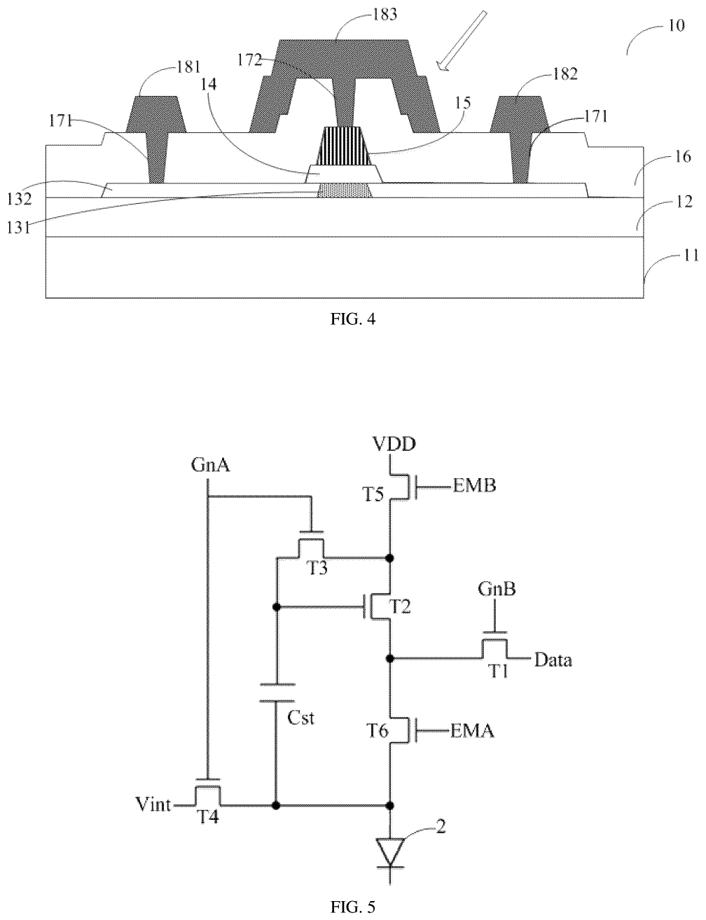

In order to solve the above technical problems, optionally, as shown in FIG. 4, the interlayer insulation layer 16 further defines therein a second through hole 172 corresponding to the gate 15.

The array substrate 10 further comprises a photoresist layer 183 arranged on the interlayer insulation layer 16. The photoresist layer 183 is in connection with the gate 15 through the second through hole 172, and the photoresist layer 183 is a conductor. The source 181, the photoresist layer 183, and the drain 182 are sequentially arranged on a surface of the interlayer insulation layer 16 along the first direction.

The gate insulation layer 14 is arranged within an orthographic projection of the photoresist layer 183.

In embodiments of the present application, the source 181, the drain 182, and the photoresist layer 183 are arranged side by side on the interlayer insulation layer 16. The interlayer insulation layer 16 defines therein three through holes, which are two first through holes 171 and a second through hole 172, respectively. The source 181 and the drain 182 are in connection with the two source and drain contact regions 132 through the two first through holes 171, respectively, and the photoresist layer 183 is in connection with the gate 15 through the second through hole 172, whereby forming a current loop of the thin film transistor.

Along the first direction, the size of the photoresist layer 183 is larger than the size of the gate insulation layer 14, and the size of the gate insulation layer 14 is larger than the size of the channel region 131. That is, viewed from the first direction, the gate insulation layer 14 is arranged within the orthographic projection of the photoresist layer 183, the channel region 131 is arranged within the orthographic projection of the gate insulation layer 14, the gate insulation layer 14 covers the channel region 131, and the photoresist layer 183 covers the gate insulation layer 14. For the channel region 131, a two-layer shielding structure is formed thereabove. By shielding light with the shielding structure, the light influence of the OLED devices 2 arranged above is lowered, and the irradiation of light onto the channel region 131 is therefore alleviated, such that generation of photogenerated carriers in the channel region 131 is alleviated to a certain extent, which reduces the leakage current of the array substrate 10, improves the stability of the array substrate 10, and improves the display effect of the display device.

In addition, after the fabrication of the source 181 and the drain 182, the array substrate 10 will be further insulated and packaged, for example, an insulating layer will be arranged above the source 181 and the drain 182. During the insulation and package process, silicon nitride, silicon oxide, and other materials may be adopted, the chemical vapor deposition process of silicon nitride requires the introduction of ammonia gas, which may make excess hydrogen easily diffuse vertically into the channel region 131 along the first direction. By providing the photoresist layer 183, the diffusion of hydrogen elements into the channel region 131 can be reduced, and the stability of the array substrate 10 can be further improved.

### EXAMPLE 3

Based on Example 2, as shown in FIG. 5, the unit driving circuit has a 6T1C structure, which comprises: a first thin film transistor T1, a second thin film transistor T2, a third thin film transistor T3, a fourth thin film transistor T4, a fifth thin film transistor T5, a sixth thin film transistor T6, and a capacitor C. A drain 182 of the fifth thin film transistor T5 is in connection with a power signal VDD. A source 181 of the fifth thin film transistor T5, a drain 182 of the third thin film transistor T3, and a drain 182 of the second thin film transistor T2 are connected in common. A source 181 of the third thin film transistor T3, a gate 15 of the second thin film transistor T2, and a first terminal of the capacitor C are connected in common. A gate 15 of the third thin film transistor T3 and a gate 15 of the fourth thin film transistor T4 are connected in common and are in connection with a first gate control line for receiving a first gate control signal GnA. A source 181 of the second thin film transistor T2, a source 181 of the first thin film transistor T1 and a drain 182 of the sixth thin film transistor T6 are connected in common. A drain 182 of the first thin film transistor T1 is in connection with a data line for receiving a data signal Data. A source 181 of the sixth thin film transistor T6, a source 181 of the fourth thin film transistor T4 and a second terminal of the capacitor C are connected in common and are in connection with an anode of an OLED device 2. A gate 15 of the first thin film transistor T1 is in connection with a second gate control line for receiving a second gate control signal GnB. A gate 15 of the fifth thin film transistor T5 is in connection with a third gate control line for receiving a third gate control signal EMB. A drain 182 of the fourth thin film transistor T4 is in connection with a reset signal line for receiving a reset signal Vint. A gate 15 of the sixth thin film transistor T6 is in connection with a fourth gate control line for receiving a fourth gate control signal EMA.

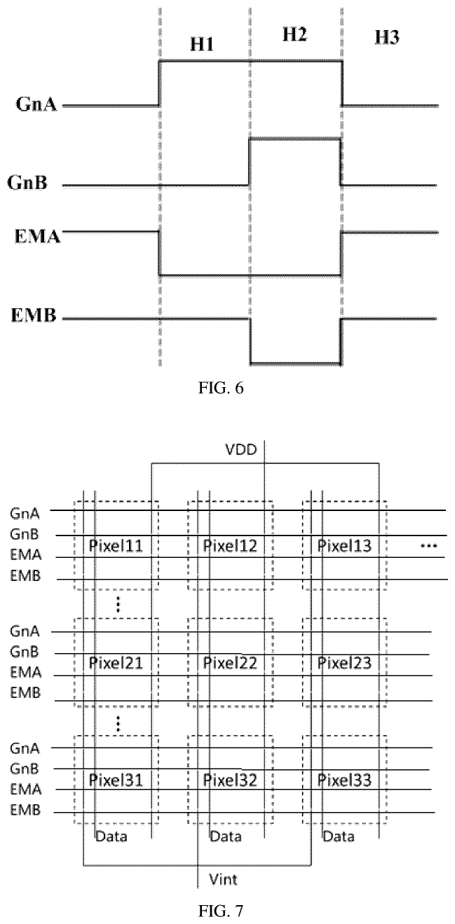

As shown in FIG. 6, an operation of each sub-pixel comprises: an initialization period H1, in which a voltage at the gate 15 of the sixth thin film transistor T6 is initialized; a sampling period H2, in which a threshold voltage of the sixth thin film transistor T6 is compensated; and a light-emitting period H3, in which OLED emits light. The initialization period H1, the sampling period H2, and the light-emitting period H3 all proceed for one line period.

The first gate control line GnA, the second gate control line GnB, the third gate control line EMB, and the fourth gate control line EMA are provided by a gate drive circuit. As shown in FIG. 7, the gate control lines are arranged on the array substrate along a second direction, and are usually transversely wired. The power signal line, the data signal line, and the reset signal line are arranged on the array substrate 10 along a third direction, and are usually longitudinally wired. The second direction intersects with the third direction. Due to the influence of a parasitic capacitance at the intersection of transverse wiring and longitudinal wiring, signal transmission delay occurs, which is not conducive to the high refresh rate requirement of OLED display panel.

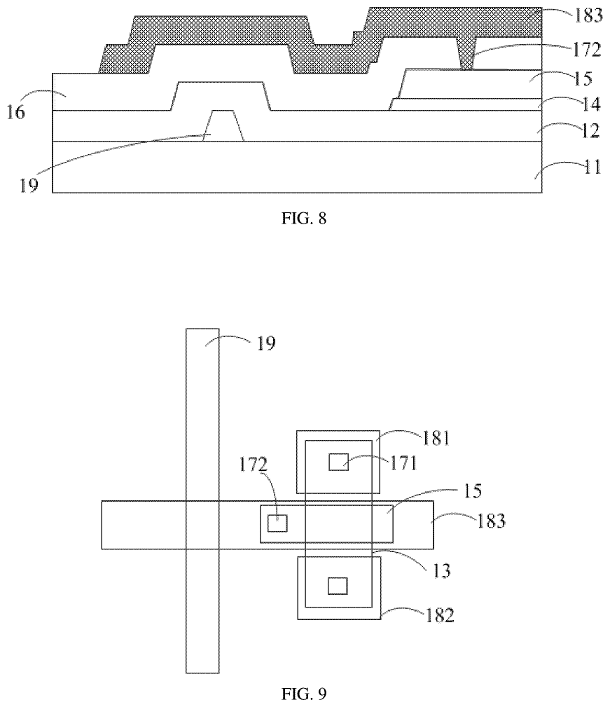

In order to solve the parasitic capacitance problem of transverse wiring and longitudinal wiring, as shown in FIG. 8, optionally, the array substrate 10 further comprises: a metal layer 19, a plurality of first wiring structures, and a plurality of second wiring structures.

The metal layer 19 is arranged between the base substrate 11 and the buffer layer 12. The buffer layer 12 covers the metal layer 19. An extension direction of the metal layer 19 intersects with an extension direction of the photoresist layer 183. In the first direction, the metal layer 19 does not overlap with the gate 15.

The plurality of first wiring structures are arranged on the array substrate 10 along a second direction. The plurality of second wiring structures are arranged on the array substrate 10 along a third direction.

The plurality of first wiring structures are wired through the photoresist layer 183.

The plurality of second wiring structures are wired through the metal layer 19.

In embodiments of the present application, as shown in FIG. 7, the array substrate 10 is provided with a plurality of first wiring structures and a plurality of second wiring structures. The plurality of first wiring structures are arranged on the array substrate 10 along a second direction. The plurality of second wiring structures are arranged on the array substrate 10 along a third direction. When the second direction is the transverse direction of the array substrate 10 and the third direction is the longitudinal direction of the array substrate 10, multiple transverse wirings and longitudinal wirings are arranged crosswise on the array substrate 10. In the traditional structure, the transverse wirings usually adopt the gate 15, and the longitudinal wirings usually adopt the source 181 and the drain 182. Since insulation layer between the source 181 and the drain 182 and the gate 15 is relatively thin, and the parasitic capacitance between the transverse and longitudinal wirings is large.

In embodiments of the present application, in order to reduce the parasitic capacitance between the transverse wiring and the longitudinal wiring, the plurality of first wiring structures are wired through the photoresist layer 183, and the plurality of second wiring structures are wired through the metal layer 19. The extension direction of the metal layer 19 is different from the extension direction of the photoresist layer 183, and there is no overlap between the metal layer 19 and the gate 15. That is, the metal layer 19 and the gate 15 are not influenced by parasitic capacitance. The corresponding transverse wiring or longitudinal wiring can be wired through the metal layer 19, the wiring in the other direction can wired through the source 181 and the drain 182 or the gate, thereby reducing the parasitic capacitance between the transverse wiring and the longitudinal wiring, reducing signal delay, and improving the high refresh rate of the OLED display panel.

In addition, the photoresist layer 183 is drilled downward to form the second through hole 172 to achieve the connection with the gate 15. In such condition, the insulation layer between the transverse wiring and the longitudinal wiring is thickest, and the parasitic capacitance is smallest, which is beneficial for the display panel to achieve the high refresh rate.

Corresponding to the arrangement of the signal lines, such as, the gate control lines, the data signal lines, the power signal lines, and the reset signal lines, optionally, the first wiring structure comprises a plurality of gate control lines.

The second wiring structure at least comprises the data signal lines, the power signal lines, and the reset signal lines.

As shown in FIG. 9, the photoresist layer 183 is intersected with the metal layer 19, a distance between the photoresist layer 183 and the metal layer 19 is the furthest, and an overlap area therebetween is the smallest. The photoresist layer 183 is in connection with the gate 15 via the second through hole 172. The source 181 and the drain 182 are in connection with the source and drain contact regions 132 through the first through holes 171, whereby forming the transverse wiring and the longitudinal wiring.

### EXAMPLE 4

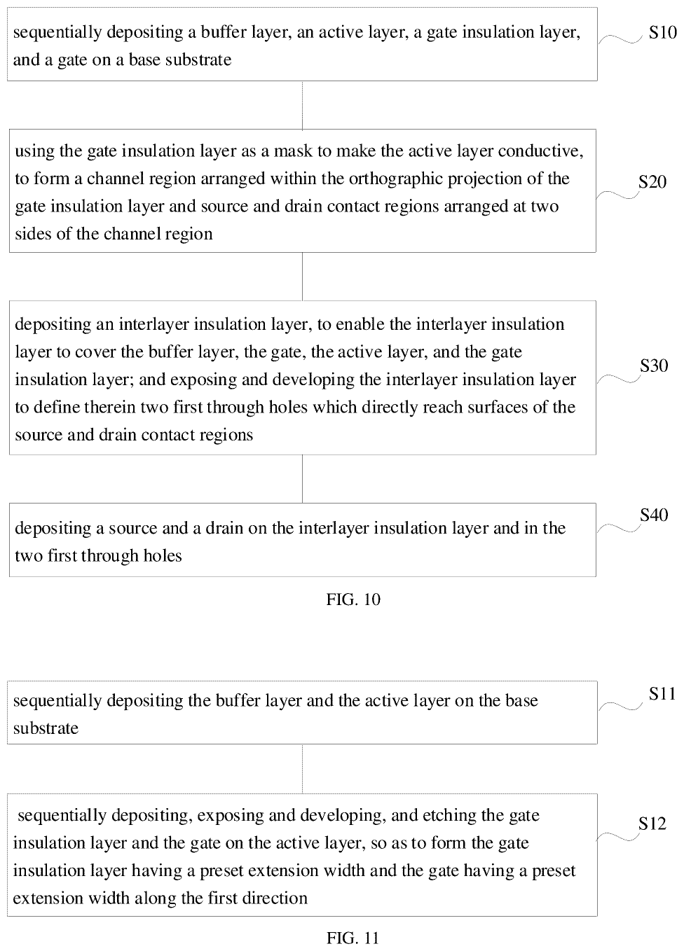

Based on the structure of the base substrate 10 provided by Example 1, embodiments of the present application further provides a method for manufacturing the base substrate 10. As shown in FIG. 10, the manufacturing method comprises steps S10-S40:

In step S10: a buffer layer 12, an active layer 13, a gate insulation layer 14, and a gate 15 are sequentially deposited on a base substrate 11, in which, the active layer 13 is an oxide semiconductor layer, and the gate 15 is arranged within an orthographic projection of the gate insulation layer 14.

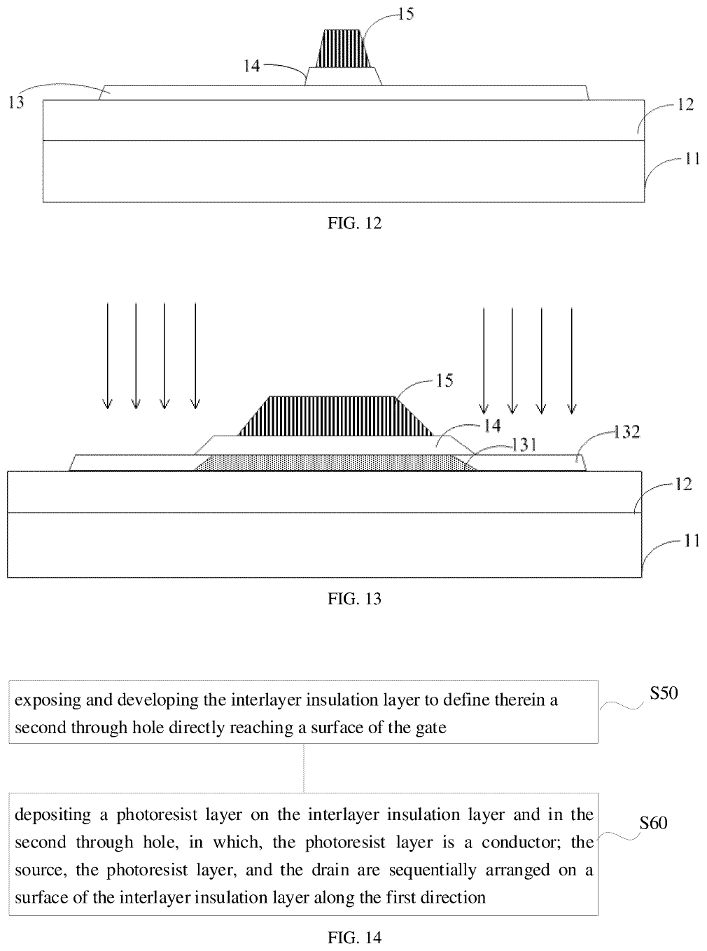

During the fabrication of the thin film transistor, the buffer layer 12, the active layer 13, the gate insulation layer 14, and the gate 15 are first stacked, a mask having a preset size is placed right above the gate 15, and then exposure and development are performed, so as to form the gate insulation layer 14 and the gate 15 having the same size, after that, the gate insulation layer 14 and the gate 15 are etched, so as to form the gate insulation layer 14 and the gate 15 having corresponding sizes, to enable the gate 15 to be placed within the orthographic projection of the gate insulation layer 14. In order to enable a difference between a width of the gate insulation layer 14 and a width of the gate 15 within a preset range, optionally, as shown in FIGS. 11-12, step S10 specifically comprises:

Step S11, sequentially depositing the buffer layer 12 and the active layer 13 on the base substrate 11; and

Step S12, sequentially depositing, exposing, developing, and etching the gate insulation layer 14 and the gate 15 on the active layer 13, so as to form the gate insulation layer 14 having a preset extension width and the gate 15 having a preset extension width along the first direction.

The gate insulation layer 14 and the gate 15 can be formed by chemical vapor deposition or physical vapor deposition. During initial deposition, the gate insulation layer 14 and the gate 15 have the same size as the active layer 13. In order to form corresponding shapes and sizes of the gate insulation layer 14 and the gate 15, a mask of a corresponding size is arranged above the gate 15, and the gate insulation layer 14 and the gate 15 of the same size are formed by exposure and development. Further, by improving the etching process, the gate insulation layer 14 having a preset extension width and the gate 15 having a preset extension width along the first direction are formed.

In step S20, the gate insulation layer 14 is used as a mask to make the active layer 13 conductive, to form a channel region 131, which is arranged within the orthographic projection of the gate insulation layer 14, and source and drain contact regions 132, which are arranged at two sides of the channel region 131. The channel region 131 is also arranged within an orthographic projection of the gate 15. The source and drain contact regions 132 are conductors.

In step S30, an interlayer insulation layer 16 is deposited, and the interlayer insulation layer 16 is enabled to cover the buffer layer 12, the gate 15, the active layer 13, and the gate insulation layer 14. The interlayer insulation layer 16 is exposed and developed to define therein two first through holes 171 directly reaching surfaces of the source and drain contact regions 132.

In step S40, a source 181 and a drain 182 are deposited on the interlayer insulation layer 16 and in the two first through holes 171.

As shown in FIG. 13, the gate insulation layer 14 is used as the mask to make the active layer 13 conductive, to form the channel region 131 and the source and drain contact regions 132. Based on the conductive treatment, the source and drain contact regions 132 form the conductor, and the channel region 131 maintains a semi-conductor. In case that the conductive process remains unchanged, due to the diffusion phenomenon, the difference between the width of the gate insulation layer 14 and the width of the channel region 131 remains unchanged. By adjusting the etching process, along the first direction, the width of the gate insulation layer 14 is greater than the width of the gate 15, and the width of the gate 15 is greater than the width of the channel region 131, so that the difference between the width of the gate 15 and the width of the channel region 131 is smaller than the preset value, that is, the distance between the edge of the gate 15 and the edge of the channel region 131 satisfies ΔL<(1/5)*Lgate. On the premise that the size of the thin film transistor is small enough to meet the definition of the display panel, the width of the channel region 131 is close to the width of the gate 15, so as to avoid the loss of switching characteristics of thin film transistors due to short channels. The first direction is the extension direction of the width of the channel region 131.

Among them, the width of the gate insulation layer 14 is defined as Lgi, the width of the gate 15 is defined as Lgate, the width of the channel region 131 is defined as Leff, the difference between the width of the gate insulation layer 14 and the width of the channel region 131 is defined as Ldif, the difference between the width of the gate 15 and the width of the channel region 131 is defined as ΔL, and the difference between the width of the gate insulation layer 14 and the width of the gate 15 is defined as Lbf.

By sequentially depositing, exposing, developing, and etching the gate insulation layer 14 and the gate 15 on the active layer 13, the gate insulation layer 14 having a preset extension width and the gate 15 having a preset extension width along the first direction are formed. By improving the etching process and adjusting the appropriate Lbf value, when Ldif remains unchanged, it can be ensured that ΔL is smaller than the preset value, and Lbf satisfies Ldif−Lbf≤(1/5)*Lgate. In addition, due to the different sizes of Ldif under different conductive processes, in order to ensure that ΔL is smaller than the preset value, optionally, along the first direction, the distance between the edge of the gate insulation layer 14 and the edge of the gate 15 is Lbf, and Lbf ranges between (1/20)*Lgate and (1/2)Lgate. By appropriately adjusting the Lbf, the display panel can have high definition, and at the same time the switching characteristics of the thin film transistor can be ensured.

After fabrication of the active layer 13, the gate insulation layer 14, and the gate 15, the interlayer insulation layer 16 is deposited on the active layer 13, the gate insulation layer 14, and the gate 15. Thereafter, a mask of a corresponding size is placed on the interlayer insulation layer 16, followed with exposure and development to form the first through hole 171 of corresponding size, and the source 181 and the drain 182 are then deposited inside the two first through holes 171 and on the interlayer insulation layer 16. After that, the source 181 and the drain 182 are etched to form the source 181 and the drain 182 of corresponding shapes and sizes, whereby forming a thin film transistor structure as shown in FIG. 1. The source 181 and the drain 182 form a current loop of the thin film transistor via the active layer 13 and the gate 15.

### EXAMPLE 5

Based on Example 4, as shown in FIG. 3, an simplified schematic diagram of an OLED display panel is exemplarily illustrated. The OLED display panel comprises: a first substrate 3, OLED devices 2, an array substrate 10, and a second substrate 1, which are stacked together. The array substrate 10 comprises a plurality of thin film transistors. Each thin film transistor is in connection with a corresponding OLED device 2 to transmit a driving signal. The light emitted by the OLED devices 2 may be reflected or refracted through gaps to the thin film transistors below, affecting the TFT characteristics of the channel region 131, causing a shift in TFT characteristics, and ultimately reducing the display effect of the OLED display panel.

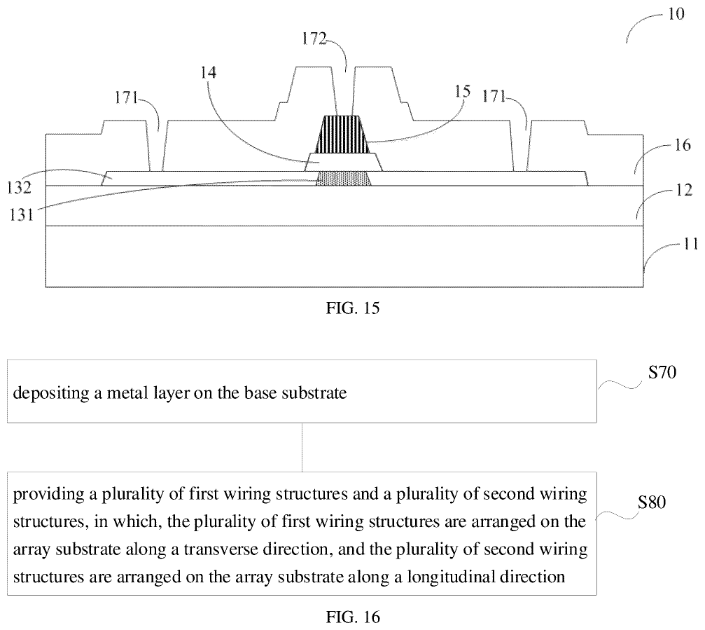

In order to solve the above technical problems, as shown in FIGS. 14-15, optionally, the method for manufacturing the array substrate 10 further comprises steps S50-S60.

In step S50, the interlayer insulation layer 16 is exposed and developed to define therein a second through hole 172 directly reaching a surface of the gate 15.

In step S60, a photoresist layer 183 is deposited on the interlayer insulation layer 16 and in the second through hole 172. The photoresist layer 183 is a conductor. The source 181, the photoresist layer 183, and the drain 182 are sequentially arranged on a surface of the interlayer insulation layer 16 along the first direction;

The gate insulation layer 14 is arranged within an orthographic projection of the photoresist layer 183.

In embodiments of the present application, the source 181, the drain 182, and the photoresist layer 183 are arranged side by side on the interlayer insulation layer 16. The interlayer insulation layer 16 defines therein three through holes, which are two first through holes 171 and a second through hole 172, respectively. The source 181 and the drain 182 are in connection with the two source and drain contact regions 132 through the two first through holes 171, respectively, and the photoresist layer 183 is in connection with the gate 15 through the second through hole 172, whereby forming a thin film transistor structure as shown in FIG. 4.

Along the first direction, the first through hole 171 and the second through holes 172 are fabricated within the same manufacturing process, and the source 181, the drain 182, and the photoresist layer 183 are fabricated within the same manufacturing process, the size of the photoresist layer 183 is larger than the size of the gate insulation layer 14, and the size of the gate insulation layer 14 is larger than the size of the channel region 131. That is, viewed from the first direction, the gate insulation layer 14 is arranged within the orthographic projection of the photoresist layer 183, the channel region 131 is arranged within the orthographic projection of the gate insulation layer 14, the gate insulation layer 14 covers the channel region 131, and the photoresist layer 183 covers the gate insulation layer 14. For the channel region 131, a two-layer shielding structure is formed thereabove. By shielding light with the shielding structure, the light influence of the OLED devices 2 arranged above is lowered, and the irradiation of light onto the channel region 131 is therefore alleviated, such that generation of photogenerated carriers in the channel region 131 is alleviated to a certain extent, which reduces the leakage current of the array substrate 10, improves the stability of the array substrate 10, and improves the display effect of the display device.

In addition, after the fabrication of the source 181 and the drain 182, the array substrate 10 will be further insulated and packaged, for example, an insulating layer will be arranged above the source 181 and the drain 182. During the insulation and package process, silicon nitride, silicon oxide, and other materials may be adopted, the chemical vapor deposition process of silicon nitride requires the introduction of ammonia gas, which may make excess hydrogen easily diffuse vertically into the channel region 131 along the first direction. By providing the photoresist layer 183, the diffusion of hydrogen elements into the channel region 131 can be reduced, and the stability of the array substrate 10 can be further improved.

### EXAMPLE 6

Based on Example 5, as shown in FIG. 5, the unit driving circuit has a 6T1C structure, which comprises: a first thin film transistor T1, a second thin film transistor T2, a third thin film transistor T3, a fourth thin film transistor T4, a fifth thin film transistor T5, a sixth thin film transistor T6, and a capacitor C. A drain 182 of the fifth thin film transistor T5 is in connection with a power signal VDD. A source 181 of the fifth thin film transistor T5, a drain 182 of the third thin film transistor T3, and a drain 182 of the second thin film transistor T2 are connected in common. A source 181 of the third thin film transistor T3, a gate 15 of the second thin film transistor T2, and a first terminal of the capacitor C are connected in common. A gate 15 of the third thin film transistor T3 and a gate 15 of the fourth thin film transistor T4 are connected in common and are in connection with a first gate control line for receiving a first gate control signal GnA. A source 181 of the second thin film transistor T2, a source 181 of the first thin film transistor T1 and a drain 182 of the sixth thin film transistor T6 are connected in common. A drain 182 of the first thin film transistor T1 is in connection with a data line for receiving a data signal Data. A source 181 of the sixth thin film transistor T6, a source 181 of the fourth thin film transistor T4 and a second terminal of the capacitor C are connected in common and are in connection with an anode of an OLED device 2. A gate 15 of the first thin film transistor T1 is in connection with a second gate control line for receiving a second gate control signal GnB. A gate 15 of the fifth thin film transistor T5 is in connection with a third gate control line for receiving a third gate control signal EMB. A drain 182 of the fourth thin film transistor T4 is in connection with a reset signal line for receiving a reset signal Vint. A gate 15 of the sixth thin film transistor T6 is in connection with a fourth gate control line for receiving a fourth gate control signal EMA.

As shown in FIG. 6, an operation of each sub-pixel comprises: an initialization period H1, in which a voltage at the gate 15 of the sixth thin film transistor T6 is initialized; a sampling period H2, in which a threshold voltage of the sixth thin film transistor T6 is compensated; and a light-emitting period H3, in which OLED emits light. The initialization period H1, the sampling period H2, and the light-emitting period H3 all proceed for one line period.

The first gate control line GnA, the second gate control line GnB, the third gate control line EMB, and the fourth gate control line EMA are provided by a gate drive circuit. As shown in FIG. 7, the gate control lines are arranged on the array substrate along a second direction, and are usually transversely wired. The power signal line, the data signal line, and the reset signal line are arranged on the array substrate 10 along a third direction, and are usually longitudinally wired. The second direction intersects with the third direction. Due to the influence of a parasitic capacitance at the intersection of transverse wiring and longitudinal wiring, signal transmission delay occurs, which is not conducive to the high refresh rate requirement of OLED display panel.

In order to solve the parasitic capacitance problem of transverse wiring and longitudinal wiring, as shown in FIG. 8, optionally, the method for manufacturing the array substrate 10 further comprises steps S70-S80.

In steps S70, a metal layer 19 is deposited on the base substrate 11. The metal layer 19 is arranged between the base substrate 11 and the buffer layer 12. The buffer layer 12 covers the metal layer 19. An extension direction of the metal layer 19 intersects with an extension direction of the photoresist layer 183. In the first direction, the metal layer 19 does not overlap with the gate 15.

In step S80, a plurality of first wiring structures and a plurality of second wiring structures are provided. The plurality of first wiring structures are arranged on the array substrate 10 along a second direction. The plurality of second wiring structures are arranged on the array substrate 10 along a third direction. The plurality of first wiring structures are wired through the photoresist layer 183. The plurality of second wiring structures are wired through the metal layer 19.

In embodiments of the present application, as shown in FIG. 7, the array substrate 10 is provided with a plurality of first wiring structures and a plurality of second wiring structures. When the second direction is the transverse direction of the array substrate 10 and the third direction is the longitudinal direction of the array substrate 10, multiple transverse wirings and longitudinal wirings are arranged crosswise on the array substrate 10. In the traditional structure, the transverse wirings usually adopt the gate 15, and the longitudinal wirings usually adopt the source 181 and the drain 182. Since insulation layer between the source 181 and the drain 182 and the gate 15 is relatively thin, and the parasitic capacitance between the transverse and longitudinal wirings is large.

In embodiments of the present application, in order to reduce the parasitic capacitance between the transverse wiring and the longitudinal wiring, the plurality of first wiring structures are wired through the photoresist layer 183, and the plurality of second wiring structures are wired through the metal layer 19. The extension direction of the metal layer 19 is different from the extension direction of the photoresist layer 183, and there is no overlap between the metal layer 19 and the gate 15. That is, the metal layer 19 and the gate 15 are not influenced by parasitic capacitance. The corresponding transverse wiring or longitudinal wiring can be wired through the metal layer 19, the wiring in the other direction can wired through the source 181 and the drain 182 or the gate, thereby reducing the parasitic capacitance between the transverse wiring and the longitudinal wiring, reducing signal delay, and improving the high refresh rate of the OLED display panel.

In addition, the photoresist layer 183 is drilled downward to form the second through hole 172 to achieve the connection with the gate 15. In such condition, the insulation layer between the transverse wiring and the longitudinal wiring is thickest, and the parasitic capacitance is smallest, which is beneficial for the display panel to achieve the high refresh rate.

Corresponding to the arrangement of the signal lines, such as, the gate control lines, the data signal lines, the power signal lines, and the reset signal lines, optionally, the first wiring structure comprises a plurality of gate control lines.

The second wiring structure at least comprises the data signal lines, the power signal lines, and the reset signal lines.

As shown in FIG. 9, the photoresist layer 183 is intersected with the metal layer 19, a distance between the photoresist layer 183 and the metal layer 19 is the furthest, and an overlap area therebetween is the smallest. The photoresist layer 183 is in connection with the gate 15 via the second through hole 172. The source 181 and the drain 182 are in connection with the source and drain contact regions 132 through the first through holes 171, whereby forming the transverse wiring and the longitudinal wiring.

### EXAMPLE 7

As shown in FIG. 3, the present application further provides a display panel, which includes an OLED device 2 and an array substrate 10. The specific structure and manufacturing method of the array substrate 10 may refer to the above embodiments. Since the display panel adopts all the technical solutions of the above-mentioned embodiments, the display panel at least have all the beneficial effects brought by the technical solutions of the above embodiments, and will not be repeated again. The OLED device is stacked above the array substrate 10.

The array substrate 10 comprises a plurality of thin film transistors. Each thin film transistor serves as a unit driving circuit and is in connection with a corresponding OLED device 2 to form a single sub-pixel. The OLED device 2 lights up according to a driving signal output by the corresponding unit driving circuit connected thereto, so that a corresponding image information can be displayed by all sub-pixels of the OLED display panel in combination.

Optionally, as shown in the simplified schematic diagram of the OLED display panel in FIG. 3, the display panel further comprises a first substrate 3 and a second substrate 1.

The first substrate 3, the OLED device 2, the array substrate 10, and the second substrate 1 are stacked. The array substrate 10 comprises a plurality of thin film transistors. The first substrate 3 and the second substrate 1 functions in fixation. The first substrate 3 and the second substrate 1 may be made of corresponding transparent materials. Optionally, in order to ensure light transmittance, the first substrate 3 and the second substrate 1 may be glass substrates.

The above-described embodiments are only used to illustrate, rather than limit, the technical solutions of the present application. Although the present application has been described in detail with reference to the foregoing embodiments, those skill in the art should understand that technical solutions described in the examples can still be modified, or some of the technical features are equivalently substituted; and these modifications or substitutions do not cause the essence of the corresponding technical solutions to deviate from the spirit and scope of the technical solutions in the embodiments of the present application, and should be included in within the protection scope of the present application.

1-13. (canceled)

14. An array substrate, comprising:
a base substrate; and
a buffer layer, an active layer, a gate insulation layer, and a gate, which are sequentially stacked on the base substrate;
wherein
the active layer is an oxide semiconductor layer, the gate is arranged within an orthographic projection of the gate insulation layer; the gate insulation layer is a conductive mask of the active layer; the active layer comprises: a channel region, which is arranged within the orthographic projection of the gate insulation layer, and source and drain contact regions, which are arranged at two sides of the channel region; the channel region is also arranged within an orthographic projection of the gate; the source and drain contact regions are conductors;
an interlayer insulation layer is formed on the buffer layer; the interlayer insulation layer covers the gate, the active layer, and the gate insulation layer; the interlayer insulation layer defines therein two first through holes, which are correspondingly arranged above the source and drain contact regions, respectively;
a source and a drain are arranged on the interlayer insulation layer, and the source and the drain are in connection with the two source and drain contact regions through the two first through holes, respectively;
wherein, the gate insulation layer and the gate are sequentially deposited, exposed and developed, and etched on the active layer, such that the gate insulation layer having a preset extension width and the gate having a preset extension width along the first direction are formed; the etching process is improved and the appropriate Lbf value is adjusted, when Ldif remains unchanged, ΔL is enabled to be smaller than a preset value, in which, Lbf represents a difference between a width of the gate insulation layer and a width of the gate, Ldif represents a difference between the width of the gate insulation layer and a width of the channel region, and ΔL represents the distance between the edge of the gate and the edge of the channel region;
along a first direction, a relationship of a distance between an edge of the gate and an edge of the channel region is as follows:
ΔL<(1/5)*Lgate,
in which, ΔL represents the distance between the edge of the gate and the edge of the channel region, Lgate represents a width of the gate extending along the first direction, and the first direction is a direction in which a width of the channel region is extended;
the array substrate further comprises:
a photoresist layer arranged on the interlayer insulation layer;
a metal layer, wherein the metal layer is arranged between the base substrate and the buffer layer; the buffer layer covers the metal layer; an extension direction of the metal layer intersects with an extension direction of the photoresist layer; in the first direction, the metal layer does not overlap with the gate; and
a plurality of first wiring structures and a plurality of second wiring structures, wherein the plurality of first wiring structures are arranged on the array substrate along a second direction; the plurality of second wiring structures are arranged on the array substrate along a third direction; the second direction intersects with the third direction;
the plurality of first wiring structures are wired through the photoresist layer; and
the plurality of second wiring structures are wired through the metal layer.

15. The array substrate of claim 14, wherein
along the first direction, the distance between the edge of the gate insulation layer and the edge of the gate is Lbf, and Lbf ranges between (1/20)*Lgate and (1/2)Lgate.

16. The array substrate of claim 14, wherein
the interlayer insulation layer further defines therein a second through hole corresponding to the gate;
the photoresist layer is in connection with the gate through the second through hole, and the photoresist layer is a conductor; the source, the photoresist layer, and the drain are sequentially arranged on a surface of the interlayer insulation layer along the first direction; and
the gate insulation layer is arranged within an orthographic projection of the photoresist layer.

17. A method for manufacturing a base substrate, comprising:
sequentially depositing a buffer layer, an active layer, a gate insulation layer, and a gate on a base substrate, in which, the active layer is an oxide semiconductor layer, and the gate is arranged within an orthographic projection of the gate insulation layer;
using the gate insulation layer as a mask to make the active layer conductive, to form a channel region arranged within the orthographic projection of the gate insulation layer and source and drain contact regions arranged at two sides of the channel region, wherein the channel region is arranged with an orthographic projection of the gate, and the source and drain contact regions are conductors;
the gate insulation layer and the gate are sequentially deposited, exposed and developed, and etched on the active layer, such that the gate insulation layer having a preset extension width and the gate having a preset extension width along the first direction are formed; the etching process is improved and the appropriate Lbf value is adjusted, when Ldif remains unchanged, ΔL is enabled to be smaller than a preset value, in which, Lbf represents a difference between a width of the gate insulation layer and a width of the gate, Ldif represents a difference between the width of the gate insulation layer and a width of the channel region, and ΔL represents the distance between the edge of the gate and the edge of the channel region;
depositing an interlayer insulation layer, to enable the interlayer insulation layer to cover the buffer layer, the gate, the active layer, and the gate insulation layer; and exposing and developing the interlayer insulation layer to define therein two first through holes which directly reach surfaces of the source and drain contact regions; and
depositing a source and a drain on the interlayer insulation layer and in the two first through holes;
wherein
along a first direction, a relationship of a distance between an edge of the gate and an edge of the channel region is as follows:
ΔL<(1/5)*Lgate,
in which, Lgate represents a width of the gate extending along the first direction, and the first direction is a direction in which a width of the channel region is extended;
the method for manufacturing the base substrate further comprises:
providing a photoresist layer on the interlayer insulation layer;
depositing a metal layer on the base substrate, wherein the metal layer is arranged between the base substrate and the buffer layer; the buffer layer covers the metal layer, and an extension direction of the metal layer intersects with an extension direction of the photoresist layer, and in the first direction, the metal layer does not overlap with the gate; and
providing a plurality of first wiring structures and a plurality of second wiring structures, wherein the plurality of first wiring structures are arranged on the array substrate along a second direction, the plurality of second wiring structures are arranged on the array substrate along a third direction, the plurality of first wiring structures are wired through the photoresist layer, the plurality of second wiring structures are wired through the metal layer, and the second direction intersects with the third direction.

18. The method of claim 17, wherein along the first direction, the distance between the edge of the gate insulation layer and the edge of the gate is Lbf, and Lbf ranges between (1/20)*Lgate and (1/2)Lgate.

19. The method of claim 17, further comprising:
exposing and developing the interlayer insulation layer to define therein a second through hole directly reaching a surface of the gate;
depositing a photoresist layer on the interlayer insulation layer and in the second through hole;
wherein
the photoresist layer is a conductor; the source, the photoresist layer, and the drain are sequentially arranged on a surface of the interlayer insulation layer along the first direction; and
the gate insulation layer is arranged within an orthographic projection of the photoresist layer.

20. The method of claim 17, wherein the step of sequentially depositing the buffer layer, the active layer, the gate insulation layer, and the gate on the base substrate comprises:
sequentially depositing the buffer layer and the active layer on the base substrate; and
sequentially depositing, exposing and developing, and etching the gate insulation layer and the gate on the active layer, so as to form the gate insulation layer having a preset extension width and the gate having a preset extension width along the first direction.
